(19) United States
(12) Patent Application Publication
(10) Pub. No.: US 2008/0082884 A1
(43) Pub. Date: Apr. 3, 2008

(54) TEST CONTROL CIRCUIT

(75) Inventor: Kousaku HARADA, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 11/859,929

(22) Filed: Sep. 24, 2007

(30) Foreign Application Priority Data
Sep. 28, 2006 (JP) 2006-264479

(51) Int. Cl. G01R 31/3187; G06F 11/27

(52) U.S. Cl. 714/733; 714/E11.169

(57) ABSTRACT

In a conventional semiconductor device, to effectively improve a toggling coefficient of a memory circuit, a test pattern and the like must be inputted from the outside, and there has been a problem that it is difficult to improve the toggling coefficient in a dynamic BT unless a high capability device is used. A test control circuit 4 according to the present invention detects the termination of a memory test executed by a BIST circuit 2A, and comprises a detector 12 for outputting a reset signal and a BIST circuit controller 13 for allowing the BIST circuit 2A to be repeatedly operated based on the reset signal.

### BACKGROUND OF THE INVENTION

1. Field of the Invention

The present invention relates to a test control circuit, and in particular, it relates to a test control circuit that detects the termination of a test and allows the test to be repeatedly executed.

2. Description of the Related Art

In a semiconductor device, a test called as a burn-in test (hereinafter, referred to as BT as the case may be) is performed to forecast a life-cycle of product and guarantee an operation after shipment. This burn-in test leaves the semiconductor device in a state supplied with a power and operable under high temperature environment for a predetermined period of time, and confirms the subsequent operation. To prepare the high temperature environment, a burn-in test device is used. Further, in recent years, according to test conditions, various burn-in tests have been proposed. For example, the test such as a static BT, a dynamic BT, and a monitor BT can be cited.

In the static BT, while applying a power to the semiconductor device so as to be put into an operable state, an input terminal of the semiconductor device is pulled up and/or down so as to be electrically fixed. That is, in the static BT, the semiconductor device is operable, but a state of the inner circuit is fixed. Just to apply the power to the semiconductor device from the outside and input a static signal, a low capability burn-in test device can be used.

In the dynamic BT, a semiconductor device is applied a power so as to be operable and is given a clock signal and a test pattern as an input signal so that the inner circuit is toggled. That is, in the dynamic BT, a load of the semiconductor device becomes higher than the static BT. By performing such a burn-in test of a high load, the semiconductor device given the dynamic BT can guarantee reliability higher than the semiconductor device tested by the static BT. However, in the dynamic BT, due to the necessity of inputting the clock signal and the test pattern from the outside, a high capability burn-in test device comprising functions to input the clock signal and the test pattern is required.

In the monitor BT, a test result is measured during the dynamic BT. That is, in the monitor BT, in addition to the function of the burn-in test device used in the dynamic BT, a burn-in test device comprising a function to measure a test result is required.

From the above, it is evident that a test is required to be performed by using a high capability burn-in test device to secure higher reliability of the semiconductor device by the burn-in test. However, since the high capability burn-in test device is generally expensive, there has been a problem that it is difficult to prepare the burn-in test device in a large quantity. Hence, Patent Document 1 discloses a technology for executing a burn-in test of higher load by a low capability burn-in test device.

The Patent Document 1 introduces a semiconductor device capable of the dynamic BT. A block diagram of a semiconductor device 100 shown in this conventional example is shown in FIG. 12. As shown in FIG. 12, the semiconductor device 100 comprises memories 107 and 108, and to allow these memories to operate during the dynamic BT, comprises a first oscillator 101, a second oscillator 103, and flip-flops 105 and 106. The first oscillator 101 and the second oscillator 103 output a clock signal of different phase respectively. A clock signal outputted by the first oscillator 101 is given to the flip-flops 105 and 106 through a selector 102 as an operation clock. Further, the clock signal outputted by the second oscillator 103 is given through a selector 104 as an input signal of the flip-flop 105. The flip-flops 105 and 106 operate as scan-chain circuits of the memories 107 and 108.

That is, the semiconductor 100, by using two clock signals different in phase, generates random access patterns for the memories 107 and 108 inside the semiconductor device 100. By these random access patterns, the dynamic BT is executed without giving signals from the outside.

[Patent Document 1] Japanese Patent Application Laid-Open No. (H)09-7394

### SUMMARY

However, since the conventional semiconductor 100 generates a random access pattern based on the phase difference of two clock signals, depending on the phase difference of the clock signal to be generated, a non-activated memory element is likely to be generated. In other words, the semiconductor device 100 has a problem that all the memory elements cannot be effectively toggled during the dynamic BT.

The test control circuit according to the present invention is comprising, a detector associated with a BIST circuit to generate a reset signal indicative of a termination of a macro (memory) test executed by said BIST circuit, and a controller (BIST circuit controller) allowing said BIST circuit to repeatedly operate in response to said reset signal.

According to the test control circuit according to the present invention, the BIST circuit is used to allow the macro (memory) to be effectively toggled, and this BIST circuit is repeatedly operated by this BIST circuit controller, thereby making it possible to effectively toggle the memory element over a long hour.

According to the test control circuit according to the present invention, the semiconductor device can be operated at high load by a low capability burn-in test device.

### BRIEF DESCRIPTION OF THE DRAWINGS

FIG. 1 is a block diagram of a semiconductor device according to a first embodiment;

FIG. 2 is a block diagram of a period counter and a detector according to the first embodiment;

FIG. 3 is a flowchart of a burn-in test according to the first embodiment;

FIG. 4 is a timing chart of the semiconductor device according to the first embodiment;

FIG. 5 is a timing chart of the semiconductor device according to the first embodiment;

FIG. 6 is a block diagram of a semiconductor device according to a second embodiment;

FIG. 7 is a timing chart of the semiconductor device according to the second embodiment;

FIG. 8 is a block diagram of a semiconductor device according to a third embodiment;

FIG. 9 is a timing chart of the semiconductor device according to the third embodiment;

FIG. 10 is a block diagram of a semiconductor device according to a fourth embodiment;

FIG. 11 is a timing chart of the semiconductor device according to the fourth embodiment; and

FIG. 12 is a block diagram of a conventional semiconductor device.

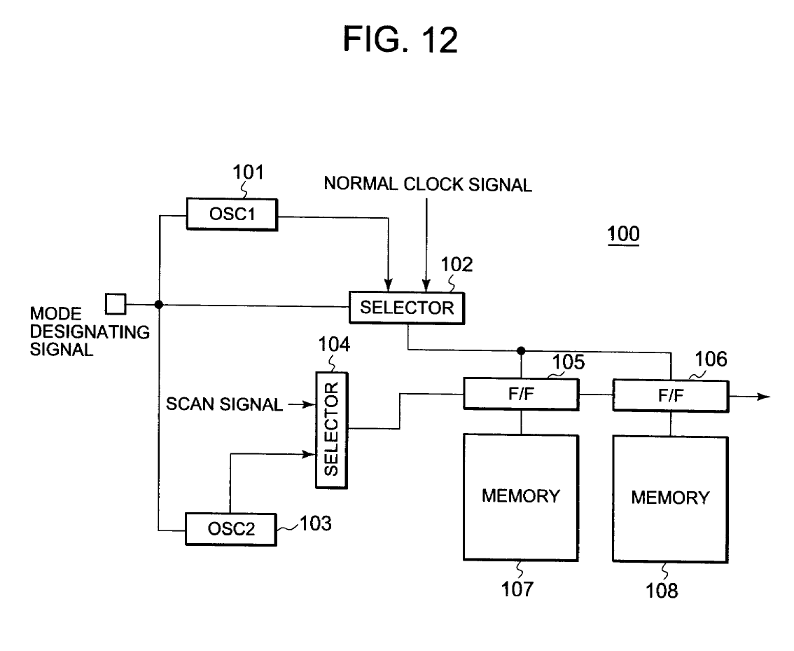

### DETAILED DESCRIPTION OF THE PREFERRED EMBODIMENTS

### First Embodiment

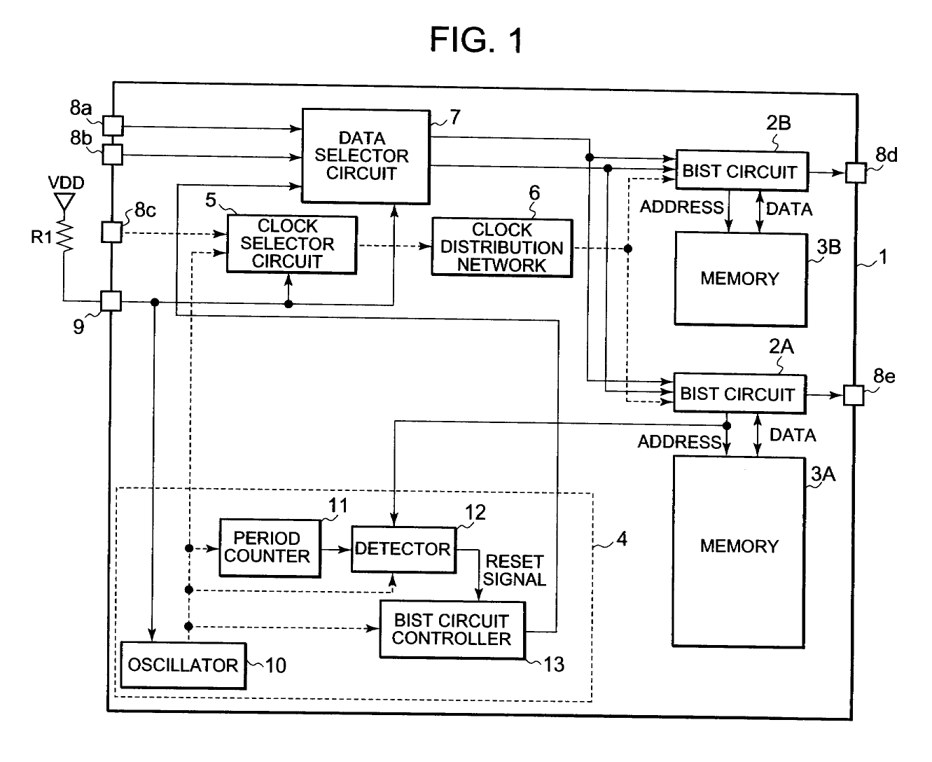

Hereinafter, embodiments of the present invention will be described with reference to the drawings. A block diagram of a semiconductor device 1 comprising a test control circuit 4 according to a first embodiment is shown in FIG. 1. As shown in FIG. 1, the semiconductor device 1 comprises, in addition to the test control circuit 4, a first BIST (Build in Self Test) circuit 2A, a first memory 3A, a second BIST circuit 2B, a second memory 3B, a clock selector circuit 5, a clock distribution network 6, and a data selector circuit 7.

The test control circuit 4 performs a control of repeatedly operating the first BIST circuit 2A and a second BIST circuit 2B. Further, the test control circuit 4 generates a clock signal for operating the first BIST circuit 2A, the first memory 3A, the second BIST circuit 2B, and the second memory 3B, and supplies this clock signal to these circuits. The detail of the test control circuit 4 will be described later.

The first BIST circuit 2A is built in the semiconductor device 1, and generates a test pattern by itself, and executes a memory test of the first memory 3A, and outputs its test result through an external terminal 8e. Incidentally, in the memory test executed by the first BIST circuit 2A, checking of the operations is performed for all the memory elements of the memory to be connected. Further, the first memory 3A is connected to the first BIST circuit 2A, and is disposed with the memory elements to perform the memory of the data. The second BIST circuit 2B and the second memory 3B are substantially the same as the first BIDT circuit 2A and the first memory 3A. Incidentally, in the present embodiment, the first memory 3A has a capacity larger than the second memory 3B. That is, the first memory 3A has a larger number of word lines than the second memory 3B.

The clock selector circuit 5 selects and outputs either of the external clock signal inputted through an external terminal 8c and the clock signal generated by the test control circuit 4 based on the voltage level of an external terminal 9. The clock distribution network 6 distributes the clock signal outputted by the clock selector circuit 5 to the first BIST circuit 2A, the second BIST circuit 2B, the first memory 3A, and the second memory 3B. At this time, the clock distribution network 6 adjusts the phase of the clock signal reaching each circuit to be approximately the same. The data selector circuit 7 selects either of the data signal inputted through the external terminal 8a and the external terminal 8e and the BIST signal outputted by the test control circuit 4 according to the voltage level of the external terminal 9, and outputs it to the first BIST circuit 2A and the second BIST circuit 2B.

Here, the test control circuit 4 will be described in detail. The test control circuit 4 comprises an oscillator 10, a period counter 11, a detector 12, and a BIST circuit controller 13. The oscillator 10 is, for example, a circuit such as a ring oscillator, and outputs a clock signal having a predetermined frequency. This oscillator 10 operates a voltage level of the external terminal 9 as an enable signal. In the example of FIG. 1, since the external terminal 9 is pulled up to a power voltage VDD through a resistor R1, the voltage level of the external terminal 9 becomes high (for example, power voltage). The enable signal shows a burn-in mode when the external terminal 9 is at high level, and the oscillator 10 operates. On the other hand, when the external terminal 9 is pulled down to a ground voltage VSS through a resistor, a voltage level of the external terminal 9 becomes low (for example, ground potential). In this case, the enable signal shows a normal operation mode, and the oscillator 10 stops operating. Further based on the clock signal generated by the oscillator 10, the period counter 11, the detector 12, and the BIST circuit controller 13 start operating.

In other words, the burr-in mode is a mode in which the semiconductor device 1 operates based on the clock signal generated by the oscillator 10. At this time, the clock selector circuit 5 outputs the clock signal generated by the oscillator 10, and the data selector circuit 7 selects and outputs the output signal of the BIST circuit controller 13. In contrast to this, the normal operation mode is a mode in which, for example, the semiconductor device 1 operates based on the external clock signal inputted from the external terminal 8c.

The period counter 11 counts the number of clocks of the clock signal generated by the oscillator 10, and outputs a reset signal at a predetermined period. The detector 12 detects that the memory test executed by the BIST circuit is terminated, and outputs a reset signal. In the present embodiment, the detector 12 detects a termination of the test based the address signal from the BIST circuit performing a test of the memory having the maximum number of words from among the memories serving as the test objects. In the example shown in FIG. 1, based on the address signal outputted by the first BIST circuit 2A, the termination of the test is detected. Incidentally, the reset signal outputted by the detector 12 is generated based on a logical sum of the reset signal outputted by the period counter 11 and the reset signal generated based on the detection by the detector 12 of the terminal of the memory test. In the following, to differentiate the rest signals, the reset signal outputted by the period counter 11 is referred to as a period reset signal (first reset signal), and the reset signal generated based on the detection by the detector 12 of the termination of the memory test is referred to as a termination reset signal (second reset signal). The reset signal generated based on the logical sum of this period reset signal and the termination reset signal is simply referred to as a reset signal.

The BIST circuit controller 13, based on the reset signal outputted from the detector 12, controls the first BIST circuit 2A and the second BIST circuit 2B. In the present embodiment, the BIST circuit controller 13 resets the first BIST circuit 2A and the second BIST circuit 2B according to the switching over from a low level to a high lever of the rest signal. The first BIST circuit 2A and the second BIST circuit 2B, based on this rest, take a test state as an initial state, and execute the test from the beginning.

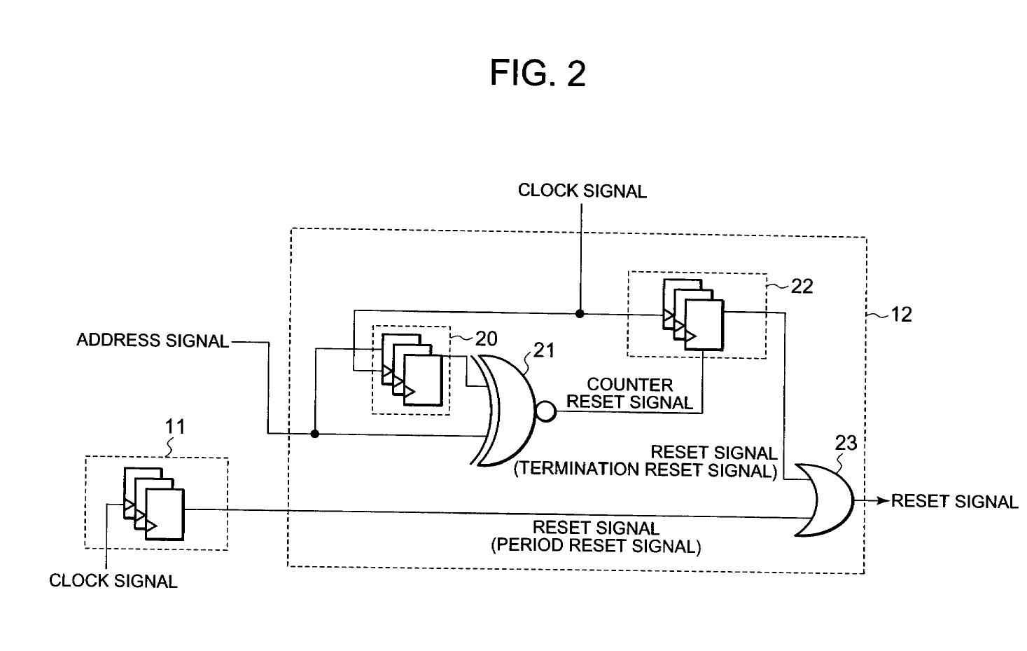

The period counter 11 and the detector 12 will be described more in detail. The block diagrams of the period counter 11 and the detector 12 are shown in FIG. 2. As shown in FIG. 2, the period counter 11 is, for example, a counter comprising a plurality of flip-flops. The period counter 11, for example, outputs the period reset signal when the number of clocks counted reaches a predetermined number of clocks.

The detector 12 comprises a address buffer 20, an EX-NOR circuit 21, a BIST termination counter 22, and an OR circuit 23. The address buffer 20, for example, holds the address of the memory outputted by the first BIST circuit 2A according to the rise edge of the clock signal at that time. The EX-NOR circuit 21 outputs an inversion signal of an exclusive-OR with the address signal outputted by the address buffer 20 and the address signal outputted by the first BIST circuit 2A. Further, the signal outputted by this EX-NOR circuit 21 is outputted to the BIST termination counter 22 as a counter reset signal. In other words, the counter reset signal becomes high when the address signal outputted by the address buffer 20 and the address signal outputted from the first BIST circuit 2A correspond to each other, and becomes low when not corresponding to each other.

The BIST termination counter 22, for example, is a counter comprising a plurality of flip-flops attached with reset. This flip-flop attached with reset is put into a reset state when the counter reset signal becomes low, and outputs a low signal. On the other hand, when the counter reset signal is at high level, a reset state of the flip-flop attached with reset is released, and the counter counts the number of clocks. The BIST termination counter 22, for example, outputs the termination reset signal when having counted 3000 pieces of clocks. The OR circuit 23 outputs a reset signal based on the logical sum of the termination reset signal and the period reset signal. In other words, by the operation of the OR circuit 23, the reset signal becomes high when at least either of the termination reset signal and the period reset signal is at high level.

Being configured as described above, the detector 12 of the present embodiment, assuming that the test is terminated when the value of the address signal outputted by the first BIST circuit 2A does not change for a predetermined period of time (for example, for a period of time equivalent to 3000 clocks), detects such an assumption as an established fact. Incidentally, the predetermined period of time can be taken as the desired number of clocks, that is, the desired period of time by changing the configuration of the BIST termination counter 22.

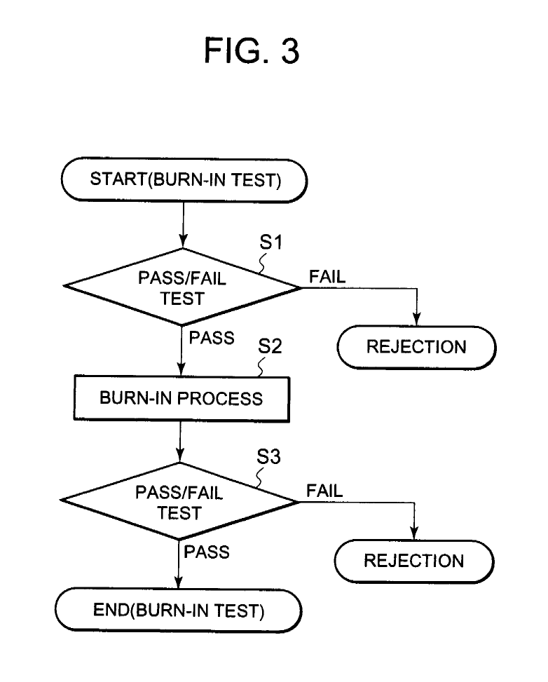

The semiconductor device 1 according to the present embodiment operates based on the test control circuit by the burn-in process in the burn-in test. This burn-in test will be described. A flow chart of the burn-in test is shown in FIG. 3. As shown in FIG. 3, the burn-in test is roughly divided into three steps. First, when the burn-in test starts, a fair-quality judgment (Pass/fail test) on the semiconductor device 1 is performed (step S1). At step S1, for example, by using a device such as a tester, an inspection is conducted as to whether the semiconductor device 1 operates without malfunction. When a defect is found in the semiconductor device 1, that semiconductor device 1 is destroyed (or rejected), and when no defect is found, the process advances to step S2.

The step S2 is a burn-in process, and the power is supplied to the semiconductor device 1, and based on the operation of the test control circuit 4, the first BIST circuit 2A, the first memory 3A, the second BIST circuit 2B, and the second memory 3B are operated. At the burn-in process, the semiconductor device 1 is put into a burn-in test device, and is operated under high temperature environment. The operation of the semiconductor device 1 during the burn-in process will be described later in detail.

When step S2 is terminated, at step S3, the same fair quality judgment (Pass/fail test) as step S1 is performed. When the semiconductor device 1 is judged as a fair-quality product at step S3, the test on the semiconductor device 1 is terminated as having passed the test. On the other hand, when judged as defective, the semiconductor device 1 is either destroyed (or rejected) or becomes a chip for analysis for checking a cause of the rejection from the burn-in test.

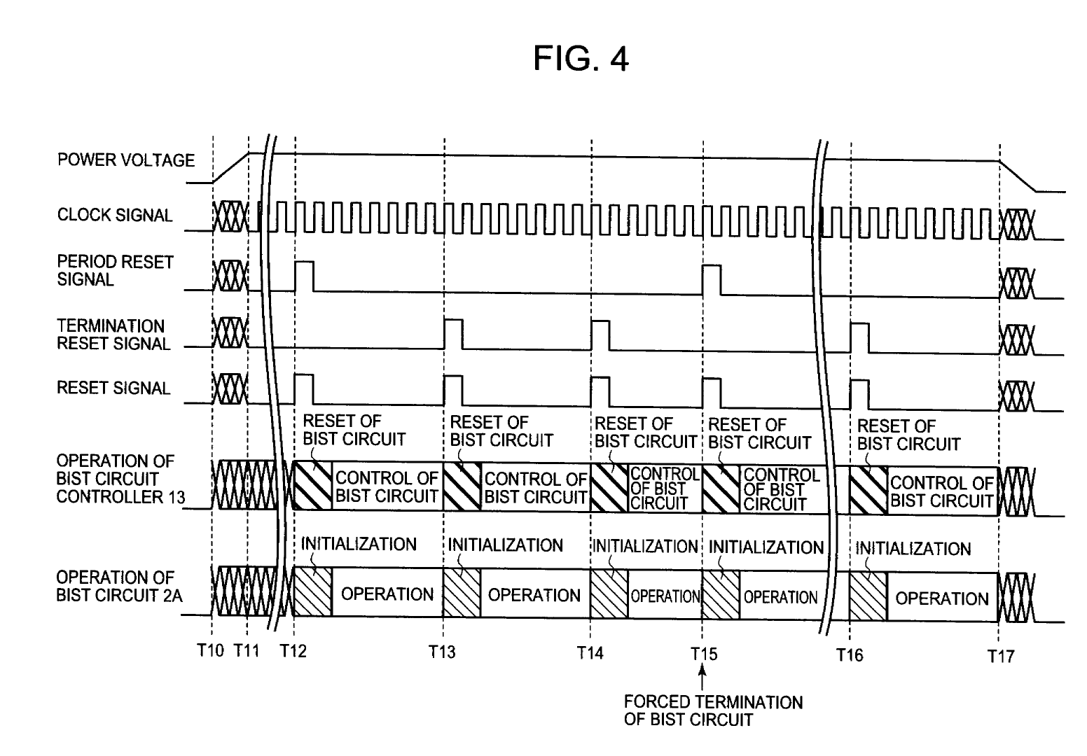

Here, the operation of the semiconductor device 1 in the burn-in step will be described. A timing chart showing the operation of the semiconductor device 1 at this time is shown in FIG. 4. Incidentally, in FIG. 4, the timing chart of the BIST circuit has shown the first BIST circuit 2A only, which supplies the address signal to the detector 12. Further, the waveform of the clock signal of FIG. 4 is just schematic, while an actual clock signal is much faster frequency. In the aforementioned description, though the external terminals 8a to 8c, 8d, and 8e have not been connected with anything particularly, when heated by the burn-in test device, these terminals are preferably pulled up to apply a voltage load on these terminals.

Referring to FIG. 4, the operation of the semiconductor device 1 will be described. First, at timing T10, the power rises up, and at timing T11, when the power voltage is stabilized, the operation of the semiconductor device 1 starts. In the present embodiment, since the external terminal 9 is pulled up, an enable signal shows a burn-in mode. Consequently, subsequent to timing T11, based on the clock signal outputted by the oscillator 10, the semiconductor device 1 operates. At timing T12 after having elapsed a predetermined period of time from timing T1, a period reset signal rises up.

Since this period reset signal becomes a reset signal through the detector 12, at timing T12, the reset signal rises up. According to the rising up of the reset signal, the BIST circuit controller 13 resets the first BIST circuit 2A. According to this resetting, the first BIST circuit 2A restores the BIST state to the initial state, and executes the BIST from the beginning. Further, the BIST circuit controller 13 at this time is put into a mode for controlling the first BIST circuit 2A.

Subsequently, at timing T13, when the BIST operation of the first BIST circuit 2A is terminated, the detector 12 detects the termination of this BIST, and based on the termination reset signal, outputs the reset signal. As a result, the reset signal rises up. According to the rising up of this reset signal, the BIST circuit controller 13 resets the first BIST circuit 2A. According to this resetting, the first BIST circuit 2A restores the BIST state to the initial state, and executes the BIST from the beginning. Further, the BIST circuit controller 13 at this time is put into a mode for controlling the first BIST circuit 2A.

In other words, when the rising up of the reset signal is inputted to the BIST circuit controller 13, the BIST circuit controller 13 resets the first BIST circuit 2A, and instructs the first BIST circuit 2A to re-execute the BIST. At timings T14 and T16, the first BIST circuit 2A is controlled so as to re-execute the BIST by such operation.

On the other hand, the reset signal at timing T15 rises up based on the period reset signal. At this timing T15, the first BIST circuit 2A is in the middle of executing the BIST. However, by the rising up of the reset signal, the BIST circuit controller 13 instructs the first BIST circuit 2A to reset. As a result, the BIST which has been executed by the first BIST circuit 2A up to this point is forcibly terminated. The first BIST circuit 2A restores the BIST state to the initial state, and executes the BIST from the beginning.

In this manner, the semiconductor device according to the present embodiment detects the termination of the BIST by the detector 12 of the test control circuit 4, and generates the reset signal. According to this reset signal, the BIST circuit controller 13 controls the first BIST circuit 2A so that the BIST is repeatedly executed. Further, even by the period reset signal periodically generated, the reset signal can be controlled, and therefore, according to this period, the BIST circuit controller 13 controls the first BIST circuit 2A so that the BIST is repeatedly executed.

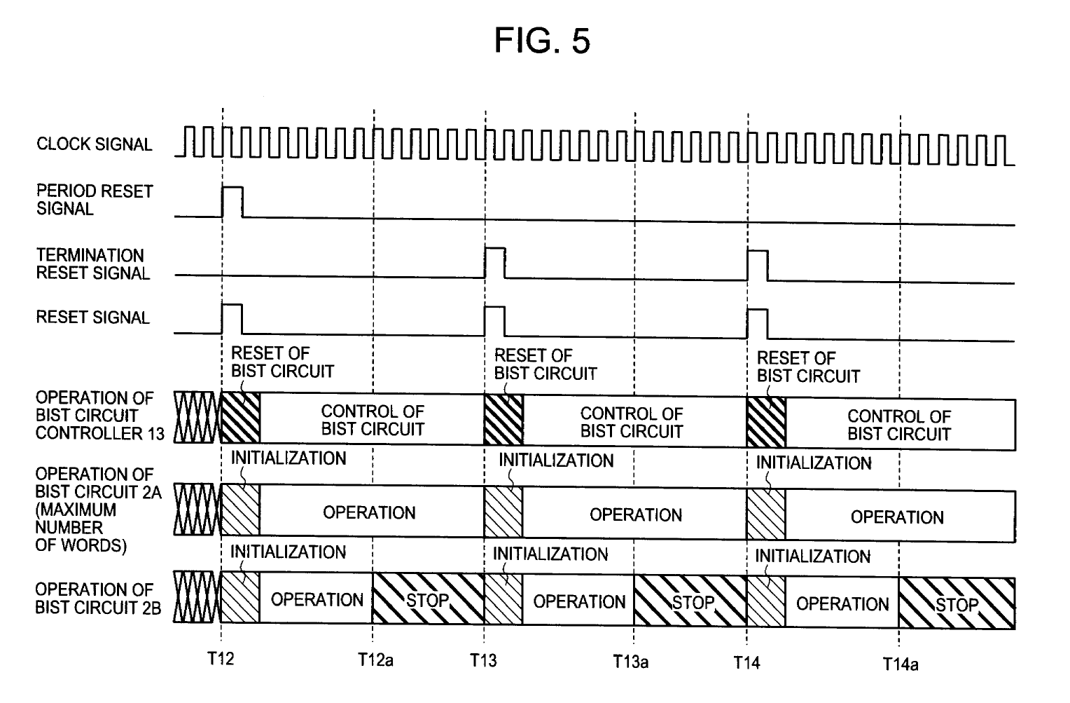

Further, in the present embodiment, the second BIST circuit 2B is also controlled by the BIST circuit controller 13 so that the BIST is repeated executed similarly to the first BIST circuit 2A. Here, the operation of the semiconductor device 1 including the operation of the second BIST circuit 28 will be described. In FIG. 5 is shown a flowchart of the semiconductor device 1 including the operation of the second BIST circuit 2B. Incidentally, the flowchart shown in FIG. 5 pays a particular attention to the period of the portion from immediately before T12 of the timing chart of FIG. 4 to the period immediately before T15.

As shown in FIG. 5, at timing T12, the period reset signal rises up. The detector 12 outputs this period reset signal as a reset signal. According to the rising up of the reset signal, the BIST circuit controller 13 resets the first BIST circuit 2A and the second BIST circuit 28. According to this resetting, the first BIST circuit 2A and the second BIST circuit 2B restores the BIST state to the initial state, and executes the BIST from the beginning. Further, the BIST circuit controller 13 at this time is put into a mode for controlling the first BIST circuit 2A and the second BIST circuit 2B.

After that, the BIST of the second BIST circuit 2B terminates faster than the BIST of the first BIST circuit 2A (timing T12a). This is because the second memory 3B is fewer in the number of word lines than the first memory 3A. In other words, subsequent to timing T12a, the second BIST circuit 2B is put into a stopped state. In contrast to this, the first BIST circuit 2A executes the BIST even subsequent to timing T12a.

Subsequently, at timing T13, when the BIST of the first BIST circuit 2A terminates, a termination reset signal rises up. The detector 12 outputs a reset signal based on this termination reset signal. The BIST circuit controller 13, according to the rising up of this reset signal, resets the first BIST circuit 2A and the second BIST circuit 2B. The first BIST circuit 2A and the second BIST circuit 2B restore the BIST state to the initial state, and execute the BIST from the beginning.

Incidentally, the operations of timings T13a and T14a subsequent to timing T13 are the same operation as timing T12a, and the operation of timing T14 is the same as timing T13. In other words, the second BIST circuit 2B also repeatedly executes the BIST similarly to the first BIST circuit 2A.

From the aforementioned description, it is clear that according to the semiconductor device 1 of the present embodiment, the termination of the BIST operation is detected by the test control circuit 4, and based on this detection result, the first BIST circuit 2A and the second BIST circuit 2B can be repeatedly operated. These first BIST circuit 2A and second BIST circuit 2B are designed to generate a test pattern to allow all the memories connected to be operated. Hence, in the present embodiment, the memory elements can be toggled without exception. Further, the semiconductor device 1 according to the present embodiment can be allowed to repeatedly execute this BIST operation. As a result, a toggling coefficient of the memory during the application of the power in the burn-in process can be effectively improved.

Further, according to the semiconductor device 1 of the present embodiment, since the oscillator 10 and the BIST circuit are built-in the semiconductor device 1, the BIST circuit can be operated without giving any particular signal from the outside in the burn-in process. In other words, the semiconductor device 1 of the present embodiment can perform a dynamic BT while using a low capability burn-in test device. Further, the semiconductor device 1 of the present embodiment outputs a period reset signal at a predetermined period, and outputs a reset signal based on this period reset signal. As a result, for example, even when the BIST circuit runaways and the test is not yet terminated, the operation of the BIST circuit can be forcibly initialized, and thus, the runaway of the BIST circuit does not affect other feedback. In other words, by stabilizing the BIST circuit by this period reset signal, the toggling efficient of the memory can be effectively improved.

Incidentally, in the above described embodiment, though a description has been made on the example in which the test control circuit 4 is built-in the semiconductor device, for example, the test control circuit 4 may be disposed by separating from the semiconductor device 1. For example, together with the semiconductor device in the burn-in process mounted with a plurality of semiconductor devices, the test control circuit 4 may be mounted on a burn-in board put into the burn-in test device. In this case, there is no need for the clock selector circuit 5 and the data selector circuit 7.

Further, a method for detecting the termination of the BIST is also not limited to the example of the above described embodiment. For example, when a value showing the final address from among the address signals outputted by the BIST circuit is inputted to the detector 12, the termination of the BIST may be detected. Further, as another method, the BIST circuit is configured to separately output the test termination signal, and based on this test termination signal, the detection circuit may be allowed to detect the termination of the BIST.

### Second Embodiment

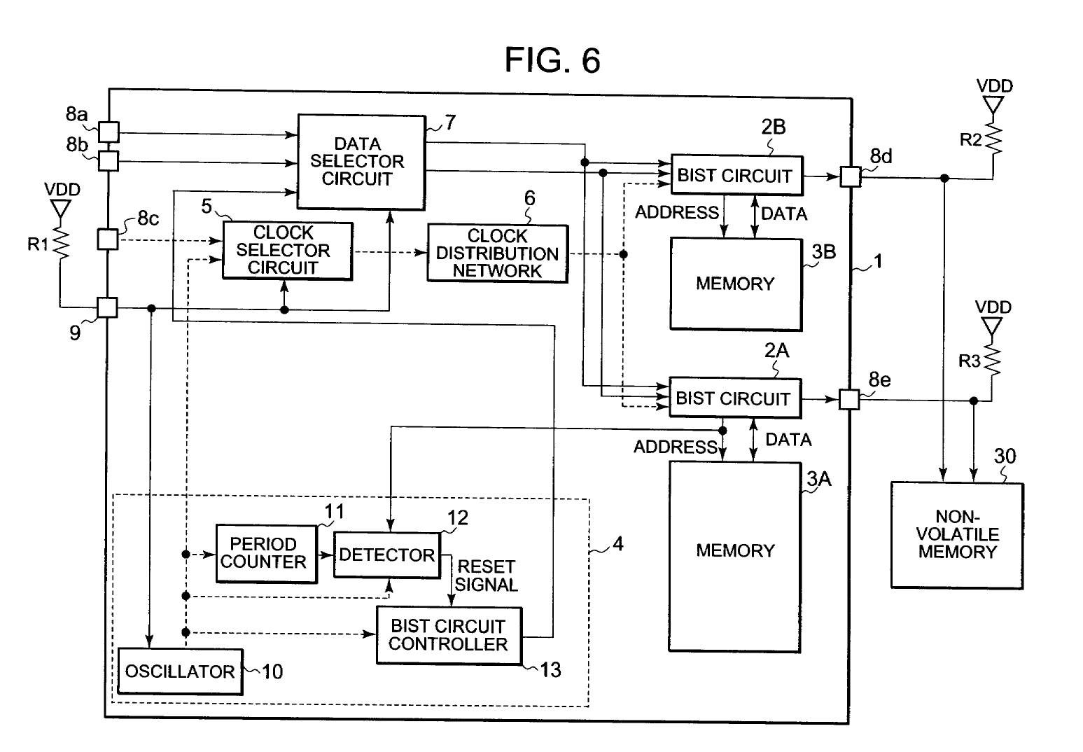

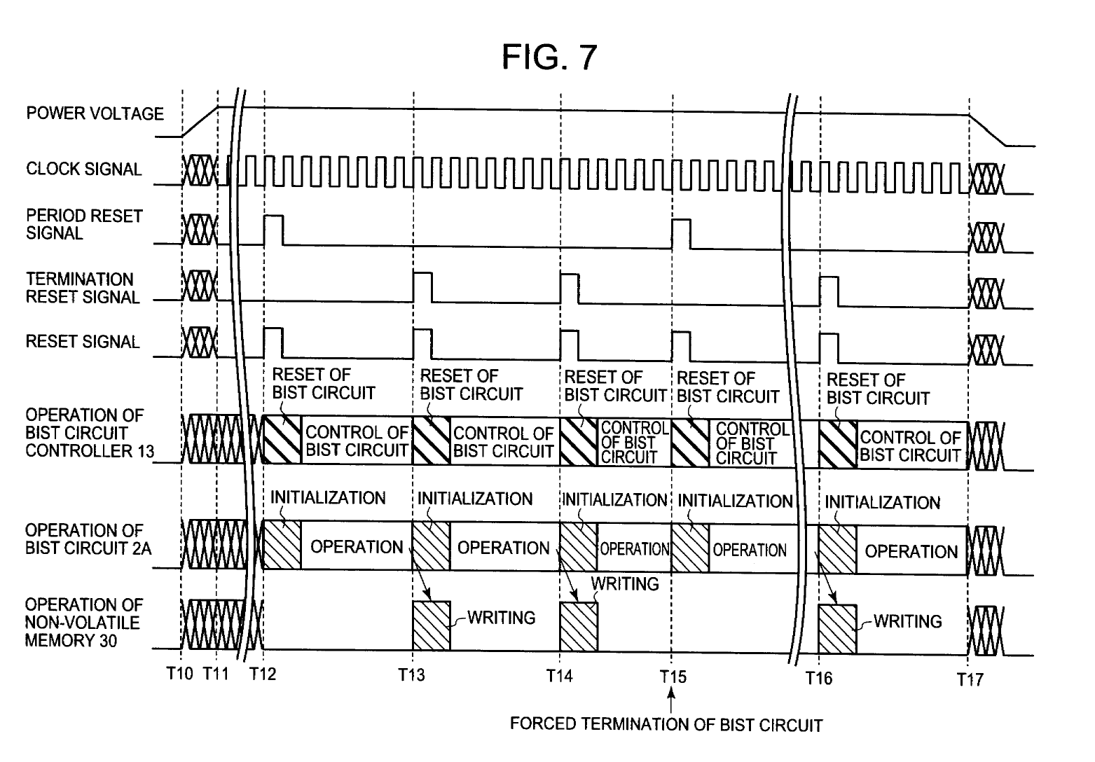

A semiconductor device 1 according to a second embodiment is configured such that the outside of the semiconductor device 1 according to the first embodiment is connected with a non-volatile memory. A block diagram of this semiconductor device 1 is shown in FIG. 6. As shown in FIG. 6, this non-volatile memory 30 is connected to the external terminal 8d of a BIST circuit 2B and the external terminal 8e of a BIST circuit 2A. At this time, the external terminal 8d is pulled up through a resistor R2, and the external terminal 8e is pulled up through a resistor R3. A non-volatile memory 30 stores a result of the memory test executed by the BIST circuit. A timing chart of the test method according to the second embodiment is shown in FIG. 7.

By using FIG. 7, the writing of the test result to a non-volatile memory 30 will be described. As shown in FIG. 7, the semiconductor device 1, at the termination of the BIST executed by the BIST circuit 2A, writes its result into the non-volatile memory 30. This writing is not performed when the BIST is forcibly terminated based on a period reset.

By reading out the result stored in this non-volatile memory 30 after taking out the semiconductor device 1 from a burn-in test device, the operation of the semiconductor device 1 inside the burn-in test device can be monitored. In other words, the semiconductor device 1 of the present embodiment can perform the monitor BT by this non-volatile memory 30 even when the burn-in test device does not comprise functions of the monitor BT. Incidentally, the non-volatile memory 30 may be built into the semiconductor device 1.

### Third Embodiment

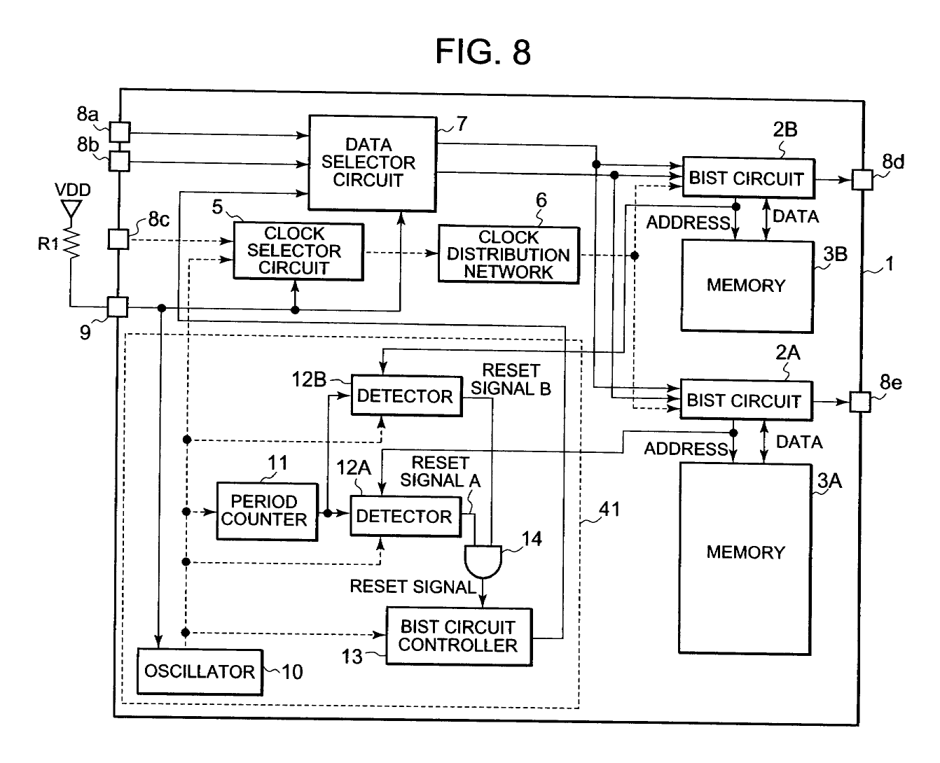

A block diagram of a semiconductor device 1 according to a third embodiment is shown in FIG. 8. As shown in FIG. 8, the semiconductor device 1 according to the third embodiment comprises a detector at every BIST circuit. In the example shown in FIG. 8, a BIST circuit 2A is connected with a detector 12A, and a BIST circuit 2B is connected with a detector 12B. Further, detectors 12A and 12B are connected with a period counter 11 respectively, and are inputted with a period reset signal. From the detectors 12A and 12B, a reset signal A and a reset signal B are outputted respectively, and are inputted to an AND circuit 14. Based on the logical sum of these two reset signals, a BIST circuit controller 13 is given a rest signal.

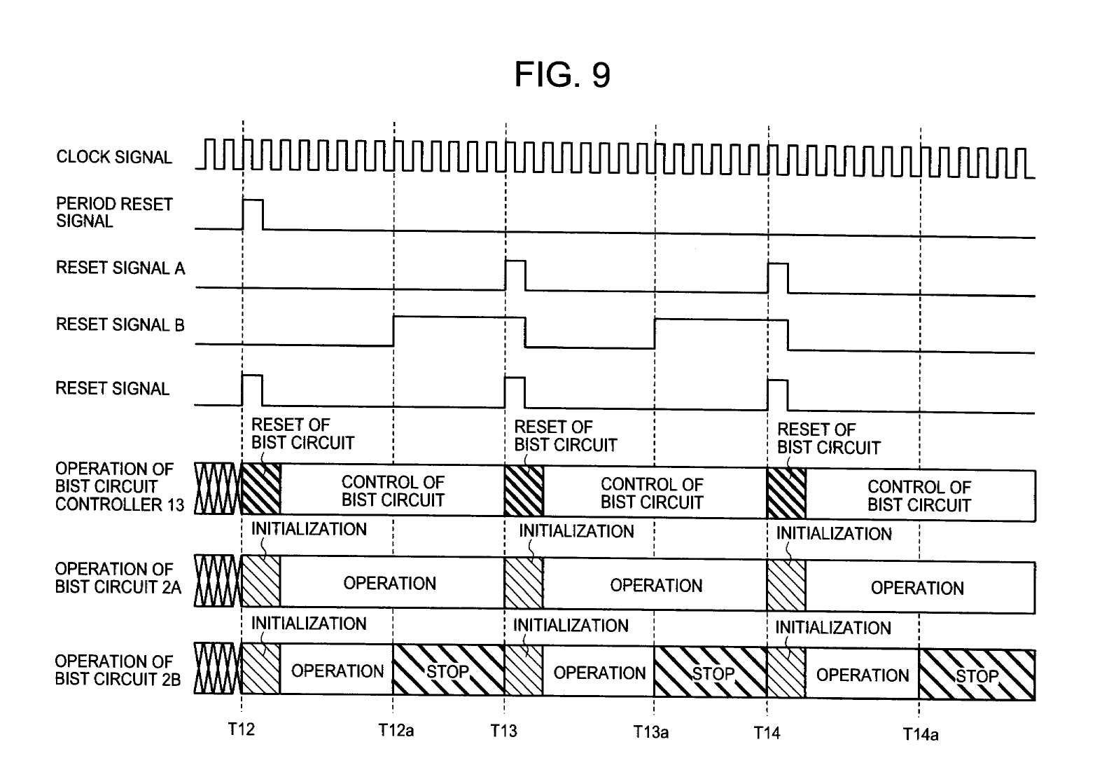

A timing chart of the operation of the semiconductor device 1 according to the third embodiment is shown in FIG. 9. As shown in FIG. 9, at timing T12a, when the BIST of the BIST circuit 2B is terminated, the reset signal B becomes high from low. At timing T13, the BIST of the BIST circuit 2A is terminated, and the reset signal A becomes high from low. As a result, both the reset signals A and B become high, and so the reset signals supplied to the BIST circuit controller 13 rise up, and the BIST circuit controller 13 resets the BIST circuits 2A and 2B. According to this resetting, the BIST circuits 2A and 2B take the BIST state as an initial state, and executes the BIST from the beginning.

In the semiconductor device 1 according to the first embodiment, for the memory to detect the termination of the BIST, it was necessary to select a memory requiring the time most for the BIST. In contrast to this, in the semiconductor device 1 according to the third embodiment, after the BISTs executed by the plurality of BIST circuits are all terminated, the reset signals are transmitted to the BIST circuit controller. In other words, the semiconductor device 1 according to the third embodiment just connects the BIST circuit and the detector without considering as to which memory takes a long time for the BIST, thereby making it possible to effectively improve the toggling coefficient.

### Fourth Embodiment

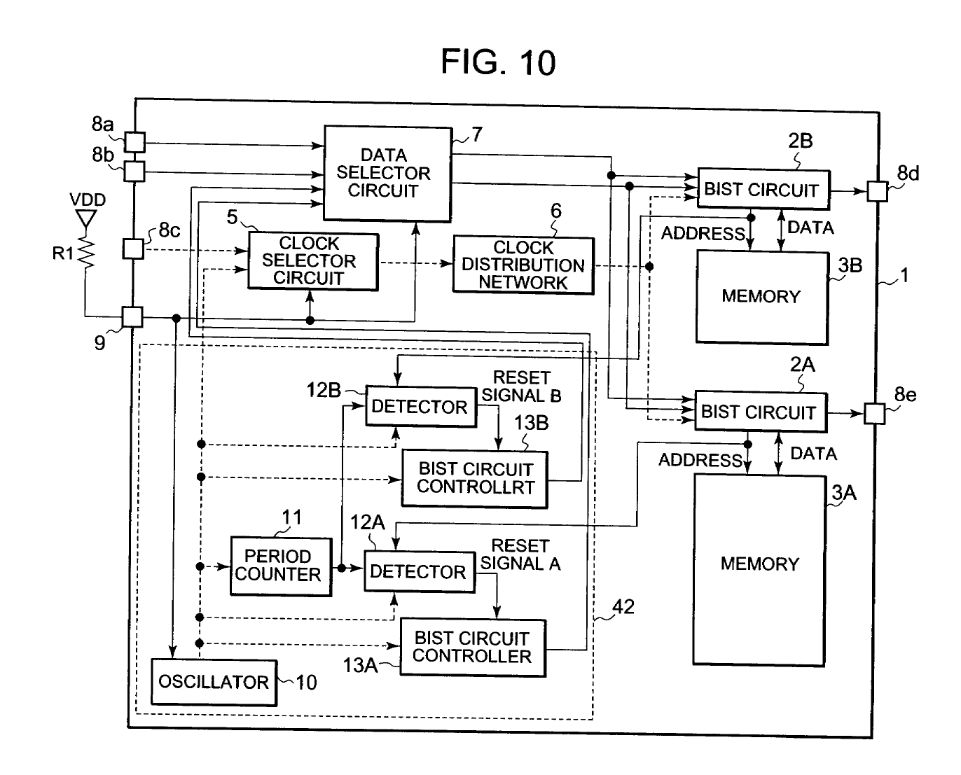

A block diagram of a semiconductor device 1 according to a fourth embodiment is shown in FIG. 10. The semiconductor device 1 according to the fourth embodiment is connected with a combination of detector and BIST circuit controller every BIST circuit. In the example shown in FIG. 10, a BIST circuit 2A is connected with a detector 12A and a BIST circuit controller 13A, and a BIST circuit 2B is connected with a detector 12B and a BIST circuit controller 13B. A plurality of BIST circuits repeatedly perform operations independently and respectively.

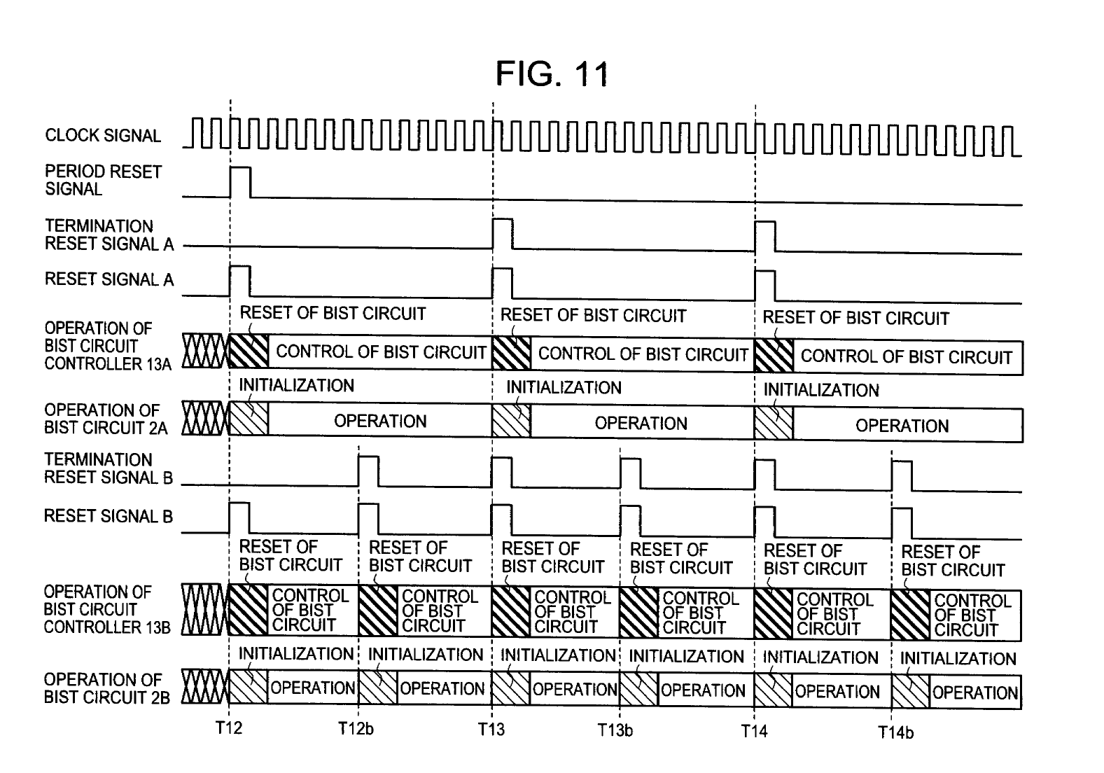

A timing chart of the operation of the semiconductor device 1 according to the fourth embodiment is shown in FIG. 11. As shown in FIG. 11, a reset signal A rises up according to the termination of the BIST of the BIST circuit 2A, and the BIST circuit controller 13A resets the BIST circuit 2A according to the rising up of this resets signal A. According to this resetting, the BIST circuit 2A repeatedly performs an operation. On the other hand, a reset signal B rises up according to the termination of the BIST of the BIST circuit 2B, and the BIST circuit controller 13B resets the BIST circuit 2B according to the rising up of this reset signal B. According to this resetting, the BIST circuit 2B repeatedly performs an operation.

In other words, in the first to third embodiments, since the BIST circuit in which the BIST quickly terminates has stopped during the period from the termination of the BIST operation to the termination of the operation of the BIST circuit in which the BIST takes a long time, the toggling coefficient has lowered. In contrast to this, in the semiconductor device 1 according to the fourth embodiment, since the BIST circuit repeatedly and independently performs the operation, a time in which the BIST circuit stops is eliminated regardless of the time required for the BIST, the toggling coefficient of the entire semiconductor device 1 can be improved.

In above described embodiments, BIST circuit is only for memory. BIST circuit is used for other macro such as Register file or I/F circuit so on. Therefore present invention of this test control circuit can use for such macro.

Incidentally, the present invention is not limited to the above described embodiments, and modifications can be made suitably without departing from the scope and spirit of the invention. For example, the detector and the period counter are not limited to the above described embodiments, and the most suitable circuit can be selected accordingly.

For example, the detector 12 can generate reset signal when the BIST circuit access the maximum address of the memory or predetermined address of the memory.

What is claimed is:

1. A test control circuit comprising:
a detector associated with a BIST circuit to generate a reset signal indicative of a termination of a macro test executed by said BIST circuit; and
a controller allowing said BIST circuit to repeatedly operate in response to said reset signal.

2. The test control circuit according to claim 1 further comprising a period counter for outputting a first reset signal every predetermined time, wherein said detector, based on either of the first reset signal and a second reset signal from said BIST circuit indicating said termination, outputs said reset signal.

3. The test control circuit according to claim 1, wherein said detector detects the termination of said test when an address of the macro generated by said BIST circuit does not change for a predetermined period of time.

4. The test control circuit according to claim 1, wherein said detector detects the termination based on a predetermined address from among the addresses of the macro generated by said BIST circuit.

5. The test control circuit according to claim 1, wherein said BIST circuit supplies a test termination signal to said detector to indicate the termination.

6. The test control circuit according to claim 1 associated with a plurality of macro sections in said macro and a plurality of BIST circuit sections in said BIST circuit, wherein said detector generates said reset signal according to the operation of one of said BIST circuit sections which generates the highest address value, and said controller, based on said reset signal, allowing said plurality of BIST circuit sections to repeatedly operate.

7. The test control circuit according to claim 1 associated with a plurality of macro sections in said macro and a plurality of BIST circuit sections in said BIST circuit, wherein said detector, based on the termination of tests by all of said plurality of BIST circuit sections, generates said reset signals, and said controller, based on said reset signal, allows said plurality of BIST circuit sections to be repeatedly operated.

8. A test circuit comprising test control circuit sections in the test control circuit according to claim 1 and BIST circuit sections in BIST circuit, wherein each of said test control circuit sections allows corresponding one of said BIST circuit sections to repeatedly operate.

9. The test control circuit according to claim 1, further comprising a non-volatile memory coupled to said BIST circuit to store a result of the test.

10. The test control circuit according to claim 1, further comprising a oscillator for generating a clock signal supplied to said BIST circuit and the macro.

11. The test control circuit according to claim 10, wherein said oscillator operates according to an externally supplied enable signal.

12. A semiconductor device comprising said test control circuit according to claim 1, said BIST circuit, and the macro tested by said BIST circuit formed on the same semiconductor substrate.

13. The semiconductor device according to claim 12, further comprising an external terminal, a controller coupled to said terminal to detect a predetermined voltage supplied to the external terminal and indicate a burn-in mode in which said BIST circuit and said macro are activated to operate.

14. A test control method of a semiconductor device comprising a macro and a BIST circuit for executing a test of the macro, wherein said method comprising:
generating a reset signal indicative of a termination of the macro test executed by said BIST circuit; and
allowing said BIST circuit to repeatedly operate in response to said reset signal.

15. The test control method of the semiconductor device according to claim 14, wherein the termination of said macro test is detected when an address of the macro generated by said BIST circuit does not change for a predetermined period of time.

16. The test control method of the semiconductor device according to claim 14, wherein the termination of said macro test is based on a predetermined address from among the addresses of the macro generated by said BIST circuit.

17. The test control method of the semiconductor device according to claim 14, wherein the termination of said macro test is supplied by said BIST circuit.
